(19) United States
(12) Patent Application Publication
(10) Pub. No.: US 2026/0344548 A1
(43) Pub. Date: Oct. 29, 2026

(54) DEVICE BONDING APPARATUS AND METHOD OF MANUFACTURING A PACKAGE USING THE APPARATUS

(71) Applicant: TAIWAN SEMICONDUCTOR MANUFACTURING COMPANY, LTD., Hsinchu (TW)

(72) Inventors: Pei-Wei WU, Pingtung (TW); Yu-Fang TSENG, Hsinchu (TW); Yi Chen HO, Taichung (TW); Chih Yuan CHANG, Hsinchu (TW)

(21) Appl. No.: 19/190,604

(22) Filed: Apr. 26, 2025

(51) Int. Cl. H10W 99/00; H10W 72/00; H10W 72/90; H10W 80/00; H10W 90/00

(52) U.S. Cl. CPC H10W 99/00; H10W 72/011; H10W 72/071; H10W 72/90; H10W 80/041; H10W 80/312; H10W 80/327; H10W 90/794

(57) ABSTRACT

A bonding apparatus and methods of operating thereof are described. The method includes heating a support to a first temperature, and a first wafer and a first die are disposed on the support. The method further includes heating a top member to a second temperature less than the first temperature and lowering the top member to press on the first die. The second temperature of the top member is increased. The method further includes lifting the top member from the first die, cooling the top member to the second temperature using a coolant, and lowering the top member to press on a second die.

### BACKGROUND

The packages of integrated circuits are becoming increasingly complex, with more device dies packaged in the same package to achieve more functions. For example, a package structure has been developed to include a plurality of device dies such as processors and memory dies in the same package. The package may include one or more dies bonded to another die to form a device/package/system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, and 3 are cross-sectional views of intermediate stages in the formation of a System on Integrate Chip (SoIC) package in accordance with some embodiments.

FIGS. 4, 5, 6, and 7 are cross-sectional side views of a bonding apparatus performing a pre-annealing process to form a package, in accordance with some embodiments.

FIG. 8 illustrates a die and a wafer being pre-bonded in the bonding apparatus, in accordance with some embodiments.

FIGS. 9, 10, 11, 12, 13, and 14 are top view of a cooling plate of the bonding apparatus, in accordance with some embodiments.

FIGS. 15, 16, and 17 are cross-sectional side views of a portion of the bonding apparatus, in accordance with some embodiments.

FIG. 18 schematic illustrates a three-way valve for controlling the flow of a coolant, in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features - but not mathematically or perfectly vertical and horizontal.

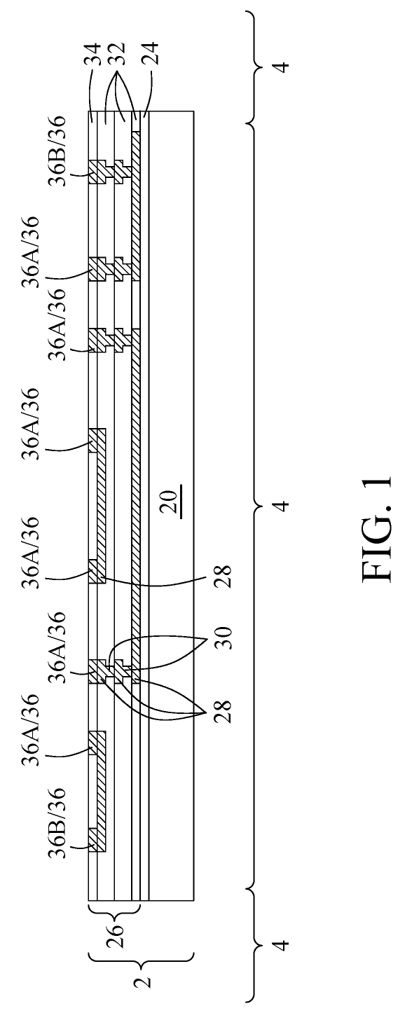

FIGS. 1, 2, and 3 are cross-sectional views of intermediate stages in the formation of a System on Integrate Chip (SoIC) package in accordance with some embodiments. FIG. 1 illustrates the cross-sectional view in the formation of a wafer 2. In accordance with some embodiments of the present disclosure, the wafer 2 is an interposer wafer, which is free from any active devices such as transistors and/or diodes therein. In accordance with some embodiments of the present disclosure, the interposer wafer 2 is also free from passive devices such as capacitors, inductors, resistors, or the like therein. The interposer wafer 2 may include a plurality of metal lines and vias therein, with some details of one of interposer dies 4 illustrated schematically. The interposer dies 4 are alternatively referred to as interposers or chips hereinafter. The interposer dies 4 are used for routing, as will be discussed in subsequent paragraphs.

The wafer 2 may include a substrate 20 and features over the top surface of the substrate 20. In accordance with some embodiments of the present disclosure, the substrate 20 is a semiconductor substrate. The substrate 20 may be formed of crystalline silicon, crystalline germanium, crystalline silicon germanium, and/or a III-V compound semiconductor such as GaAsP, AlInAs, AlGaAs, GaInAs, GaInP, GaInAsP, or the like. The substrate 20 may also be a bulk silicon substrate or a Silicon-On-Insulator (SOI) substrate. The substrate 20 may also be a dielectric substrate, which may be formed of silicon oxide, for example. In accordance with some embodiments, through-vias (not shown) are formed to extend into the substrate 20, and the through-vias are used to electrically inter-couple the features on opposite sides of the substrate 20. In accordance with alternative embodiments, no through-vias are formed extending into the substrate 20.

A dielectric layer 24 may be formed over the substrate 20. In accordance with some embodiments of the present disclosure, the dielectric layer 24 is an Inter-Layer Dielectric (ILD), which may be formed of silicon oxide, Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS), or the like. The dielectric layer 24 may be formed using thermal oxidation, spin coating, Flowable Chemical Vapor Deposition (FCVD), Atomic Layer Deposition (ALD), Chemical Vapor Deposition (CVD), Plasma Enhanced Chemical Vapor Deposition (PECVD), Low Pressure Chemical Vapor Deposition (LPCVD), or the like.

Over the dielectric layer 24 resides an interconnect structure 26. The interconnect structure 26 includes metal lines 28 and vias 30, which are formed in dielectric layers 32. The dielectric layers 32 are alternatively referred to as Inter-Metal Dielectric (IMD) layers hereinafter. In accordance with some embodiments of the present disclosure, the dielectric layers 32 are formed of low-k dielectric materials having dielectric constants (k values) lower than 3.8. For example, the k values of the dielectric layers 32 may be lower than about 3.0 or lower than about 2.5. The dielectric layers 32 may be formed of a carbon-containing low-k dielectric material, Hydrogen SilsesQuioxane (HSQ), MethylSilsesQuioxane (MSQ), or the like. In accordance with alternative embodiments of the present disclosure, some or all of the dielectric layers 32 are formed of a dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, or the like, are formed between the IMD layers 32, and are not shown for simplicity.

The metal lines 28 and vias 30 are formed in the dielectric layers 32. The metal lines 28 at a same level are collectively referred to as a metal layer hereinafter. In accordance with some embodiments of the present disclosure, the interconnect structure 26 includes a plurality of metal layers that are interconnected through the vias 30. The metal lines 28 and vias 30 may be formed of a metal, such as copper or copper alloys.

As shown in FIG. 1, a surface dielectric layer 34 is the topmost layer of the interconnect structure 26. In some embodiments, the surface dielectric layer 34 includes silicon oxide, SiON, or other suitable dielectric material. The surface dielectric layer 34 is alternatively referred to as a passivation layer since it has the function of isolating the underlying low-k dielectric layers (if any) from the adverse effect of detrimental chemicals and moisture. The surface dielectric layer 34 may also have a composite structure including more than one layer, which may be formed of silicon oxide, silicon nitride, Undoped Silicate Glass (USG), or the like. As shown in FIG. 1, bond pads 36A and 36B, which are also collectively and individually referred to as bond pads 36, are formed in the surface dielectric layer 34.

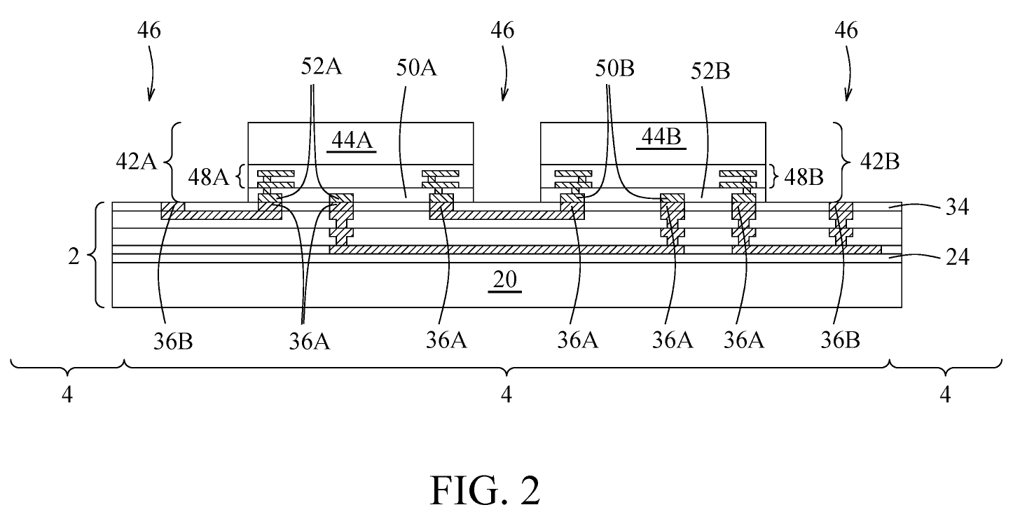

As shown in FIG. 2, device dies 42A and 42B are bonded to the wafer 2. In some embodiments, the device dies 42A and 42B are memory dies such as Dynamic Random Access Memory (DRAM) dies or Static Random Access Memory (SRAM) dies. Each of the device dies 42A and 42B may also be a Central Processing Unit (CPU) die, a Micro Control Unit (MCU) die, an input-output (IO) die, a BaseBand (BB) die, or an Application processor (AP) die. The device dies 42A and 42B may be the same type or different types of dies selected from the above-listed types. The interposer die 4, device die 42A, and device die 42B in combination function as a package, which may be a memory package or logic package.

The device dies 42A and 42B include substrates 44A and 44B, respectively, which may be semiconductor substrates such as silicon substrates. The device dies 42A and 42B may further include interconnect structures 48A and 48B, respectively, for connecting to the active devices and passive devices in device dies 42A and 42B. The interconnect structures 48A and 48B each includes metal lines and vias, which are illustrated schematically. The device die 42A includes bond pads 50A and a dielectric layer 52A at the illustrated bottom surface. The bottom surfaces of the bond pads 50A are coplanar with the bottom surface of the dielectric layer 52A. The device die 42B includes bond pads 50B and a dielectric layer 52B at the illustrated bottom surface. The bottom surfaces of the bond pads 50B are coplanar with the bottom surface of the dielectric layer 52B.

The bonding of the device dies 42A and 42B to the wafer 2 may be achieved through hybrid bonding. For example, the bond pads 50A and 50B are bonded to the bond pads 36A through metal-to-metal direct bonding. In some embodiments, the metal-to-metal direct bonding is copper-to-copper direct bonding. Furthermore, the dielectric layers 52A and 52B are bonded to the surface dielectric layer 34, for example, with covalent bonds (which may include Si—O—Si bonds) generated.

To achieve the hybrid bonding, the device dies 42A and 42B are first pre-bonded to the surface dielectric layer 34 and the bond pads 36A by lightly pressing the device dies 42A and 42B against the interposer die 4 at an elevated temperature. For example, the surface dielectric layer 34 is bonded to the dielectric layers 52A and 52B, with bonds formed therebetween, and the atoms (such as oxygen atoms) in one of the surface dielectric layer 34 and the dielectric layers 52A/52B form covalent bonds with the atoms (such as silicon atoms) in the other one of the surface dielectric layers 34 and the dielectric layer 52A/52B.

Although two device dies 42A and 42B are illustrated, the hybrid bonding may be performed at wafer level, and a plurality of device die groups identical to the illustrated die group including the device dies 42A and 42B is pre-bonded, and arranged as rows and columns.

After all the device dies 42A and 42B are pre-bonded, an anneal process is performed to cause the inter-diffusion of the metals in the bond pads 36A and the corresponding overlying bond pads 50A and 50B.

In some embodiments, the pre-bonding of the device dies 42A, 42B to the wafer 2 may be referred to as a pre-anneal process. The pre-anneal process is described in detail below. After the pre-bonding process, an anneal process is performed on the wafer 2 and the dies 42A, 42B. In some embodiments, the annealing temperature of the anneal process may be in the range between about 200 degrees Celsius and about 400 degrees Celsius, such as between about 300 degrees Celsius and about 400 degrees Celsius. The annealing time is in the range between about 1.5 hours and about 3.0 hours, such as between about 1.5 hours and about 2.5 hours, in some embodiments. Through the hybrid bonding, bond pads 50A and 50B are bonded to the corresponding bond pads 36A through direct metal bonding caused by metal inter-diffusion as a result of the anneal process.

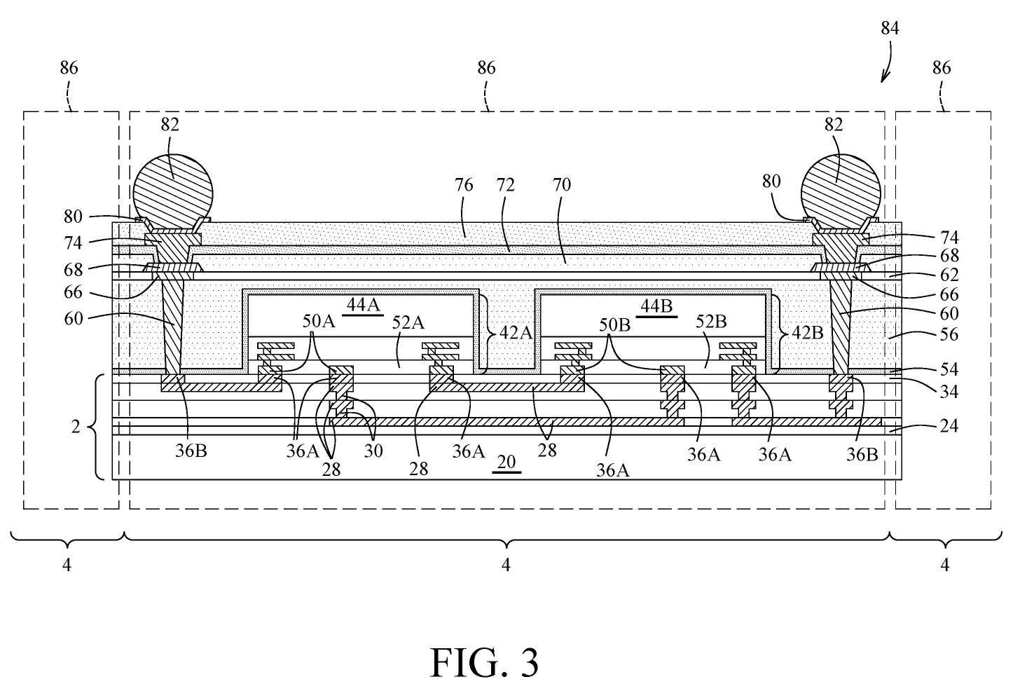

As shown in FIG. 2, gaps 46 are formed between adjacent device dies 42A, 42B. Next, as shown in FIG. 3, the gaps 46 are filled with a dielectric layer 56. In some embodiments, an etch stop layer 54 is first formed in the gaps 46, and the dielectric layer 56 is formed on the etch stop layer 54. The etch stop layer 54 may also serve as a glue layer for the dielectric layer 56. In some embodiments, the etch stop layer 54 is a nitride layer, such as SiN. In some embodiments, the etch stop layer 54 is an organic layer or a polymer layer and is formed by any suitable method. The dielectric layer 56 may be a molding material or a molding compound, such as a polymer-based material. The polymer-based material can include, for example, plastic materials, epoxy resin, polyimide, polyethylene terephthalate (PET), polyvinyl chloride (PVC), polymethylmethacrylate (PMMA), polymer components doped with fillers including fiber, clay, ceramic, inorganic particles, or any combinations thereof.

Next, as shown in FIG. 3, conductive features 60 are formed in the dielectric layer 56 and the etch stop layer 54. The conductive features 60 may be through vias and are connected to the bond pads 36B of the wafer 2. Dielectric layers 62, 70, 72, and 76 are formed over the dielectric layer 56, as shown in FIG. 3, and conductive features 66, 68, 74, and 80 are formed in the dielectric layers 62, 70, 72, and 76. In some embodiments, the dielectric layer 62 is formed of a low-k dielectric material having a k value lower than 3.8. In some embodiments, the dielectric layer 62 is formed of an oxide such as silicon oxide, a nitride such as silicon nitride, or the like. The conductive features 66 are formed in the dielectric layer 62. The conductive features 66 may include metal lines and metal pads. The conductive features 68 are formed on the conductive features 66, as shown in FIG. 3. In some embodiments, the conductive features 68 are metal pads and are formed of aluminum copper. The dielectric layer 70, which may be a passivation layer, is then formed on the conductive features 68 and the dielectric layer 62. The dielectric layer 70 may be a single layer or a composite layer. In some embodiments, the dielectric layer 70 is a composite layer including a silicon oxide layer (not shown separately), and a silicon nitride layer (not shown separately) over the silicon oxide layer. The dielectric layer 70 may also be formed of other dielectric materials, such as Un-doped Silicate Glass (USG), silicon oxynitride, and/or the like. In some embodiments, the dielectric layer 70 is an organic layer or a polymer layer and is formed by any suitable method. Next, openings are formed in the dielectric layer 70, and the dielectric layer 72 and the conductive features 74 are formed in the openings, as shown in FIG. 3. In some embodiments, the dielectric layer 72 may be a polymer layer and may be formed of polyimide, polybenzoxazole (PBO), or the like. The conductive features 74 may be redistribution lines (RDLs), and the conductive features 74 are electrically connected to the conductive features 68. The dielectric layer 76 is formed on the dielectric layer 72 and the conductive feature 74. The dielectric layer 76 may include the same material as the dielectric layer 72. Next, the conductive features 80 are formed in the dielectric layer 76 to connect to the conductive features 74. The conductive features 80 may be Under-bump metallurgies (UBMs). Next, electrical connectors 82 are formed over and contacting the UBMs 80. The electrical connectors 82 may include metal pillars, solder regions, or the like. Throughout the description, the structure shown in FIG. 3 is referred to as composite wafer 84. A die-saw (singulation) step is performed on the composite wafer 84 to separate the composite wafer 84 into a plurality of SoIC packages 86.

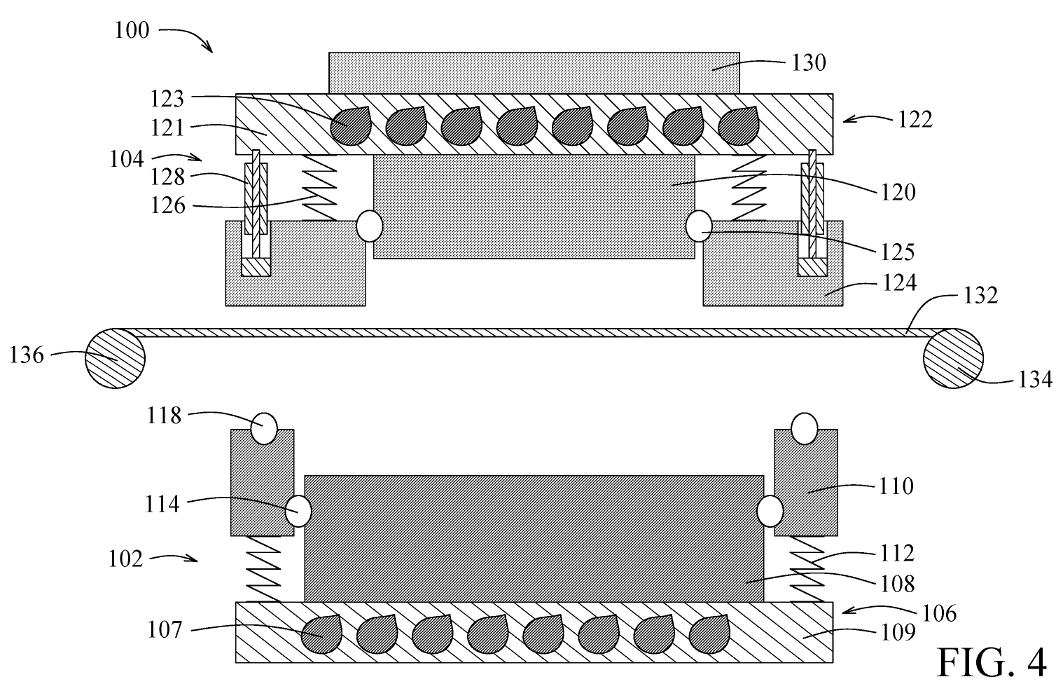

FIGS. 4, 5, 6, and 7 are cross-sectional side views of a bonding apparatus 100 performing a pre-annealing process to form a package, in accordance with some embodiments. As shown in FIG. 4, the bonding apparatus 100 includes a lower portion 102 and an upper portion 104. The lower portion 102 includes a bottom heater 106 and a support 108 disposed on the bottom heater 106. The bottom heater 106 may include one or more heating elements 107 embedded in a plate 109. The heating elements 107 may be any suitable heating elements, such as a resistive heating element. In some embodiments, the bottom heater 106 may include a heating device other than the heating element 107. The support 108 is configured to support a wafer, such as the wafer 2, and dies, such as the device dies 42A, 42B, to be bonded to the wafer. In some embodiments, the support 108 is made of a thermally conductive material, such as a metal. In some embodiments, the thermally conductive material of the support 108 may be an electrical insulator. Heat generated by the bottom heater 106 heats the wafer and the dies via the support 108. The lower portion 102 further includes a bottom clamp 110 surrounding the support 108, as shown in FIG. 4. The bottom clamp 110 is movable relative to the support 108, and the bottom clamp 110 is disposed on a coil 112, which extends from the plate 109, as shown in FIG. 4. A sealing member 114 is disposed between the bottom clamp 110 and the support 108. The sealing member 114 may be an O-ring and may seal a space between the support 108 and the bottom clamp 110. Furthermore, the sealing member 114 prevents the bottom clamp 110 from contacting the support 108 during the movement of the bottom clamp 110. Another sealing member 118 is disposed on the bottom clamp 110, as shown in FIG. 4. The sealing member 118 may include the same material as the sealing member 114.

The upper portion 104 of the bonding apparatus 100 includes a top heater 122. The top heater 122 may include a plate 121 and one or more heating elements 123 embedded in the plate 121. The one or more heating elements 123 may include the same heating elements as the one or more heating elements 107. A top member 120 is disposed below the top heater 122. The top member 120 is configured to press against the dies, such as the device dies 42A, 42B, to pre-bond the dies to the wafer, such as the wafer 2. In some embodiments, the top member 120 is a block of material made of a thermally conductive material, such as a metal. In some embodiments, the top member 120 is a metal plate. In some embodiments, the thermally conductive material of the top member 120 may be an electrical insulator. A top clamp 124 surrounds the top member 120, and a sealing member 125 is disposed between the top clamp 124 and the top member 120. The top clamp 124 is suspended from the plate 121 by a suspension member 128, and a coil 126 is disposed between the top clamp 124 and the plate 121, as shown in FIG. 4.

In some embodiments, a cooling plate 130 is disposed on the top heater 122. One or more cooling channels may be formed in the cooling plate 130 for a coolant to flow through. A release layer 132 is disposed between the upper portion 104 and the lower portion 102. The release layer 132 may be made of plastic, polymer, or epoxy. The release layer 132 may be disposed between rollers 134, 136.

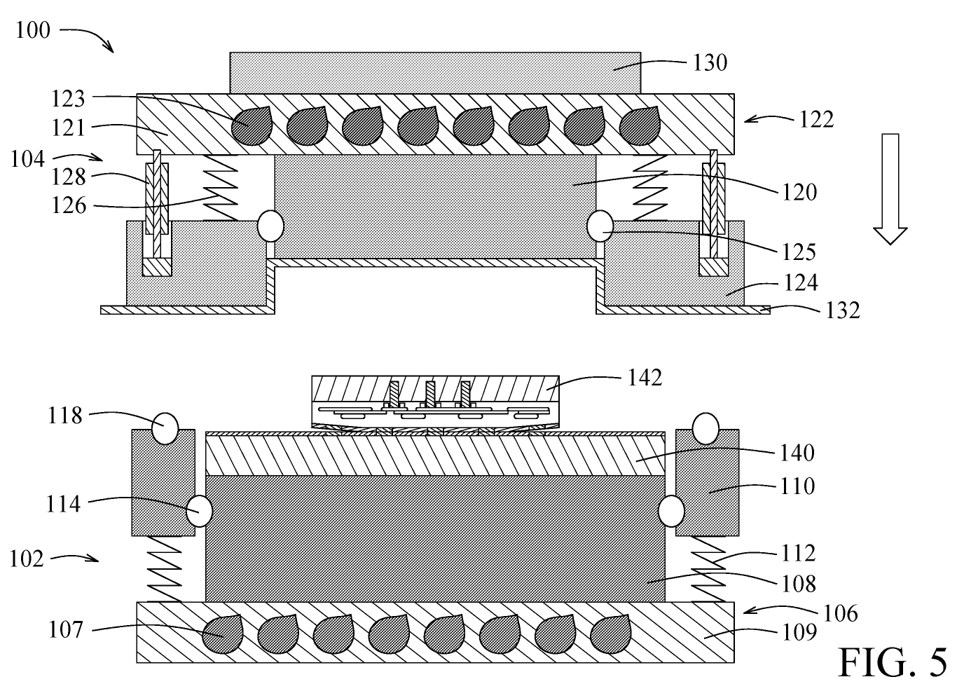

Next, as shown in FIG. 5, a wafer 140 with one or more dies 142 disposed thereon are placed on the support 108, and the upper portion 104 of the bonding apparatus 100 is lowered to be in contact with the release layer 132. The rollers 134, 136 are omitted for clarity. The wafer 140 may be the wafer 2 shown in FIG. 3, and the die 142 may be the device die 42A shown in FIG. 3. In some embodiments, multiple dies 142 are placed on the wafer 140. As shown in FIG. 5, the top surface of the wafer 140 includes bond pads, such as the bond pads 36A, 36B shown in FIG. 3, and the bottom surface of the die 142 includes bond pads, such as the bond pads 50A, 50B shown in FIG. 3. The bond pads of the wafer 140 are aligned with the bond pads of the die 142, as shown in FIG. 5. In some embodiments, the die 142 is warped, so the bottom surface of the die 142 is curved instead of being flat. For example, the bottom surface of the die 142 may have a convex profile, as shown in FIG. 5. The warpage of the die 142 may be a result of coefficient of thermal expansion (CTE) mismatch between the semiconductor material and the dielectric material of the die 142.

In some embodiments, after the upper portion 104 of the bonding apparatus 100 contacts the release layer 132, the release layer 132 may conform to the various surfaces of the upper portion 104, as shown in FIG. 5. The release layer 132 may conform to the various surfaces of the upper portion 104 by any suitable method. In some embodiments, suction channels (not shown) through the sealing member 125 are used to pull up the release layer 132, so the release layer 132 is conformal to the various surfaces of the upper portion 104.

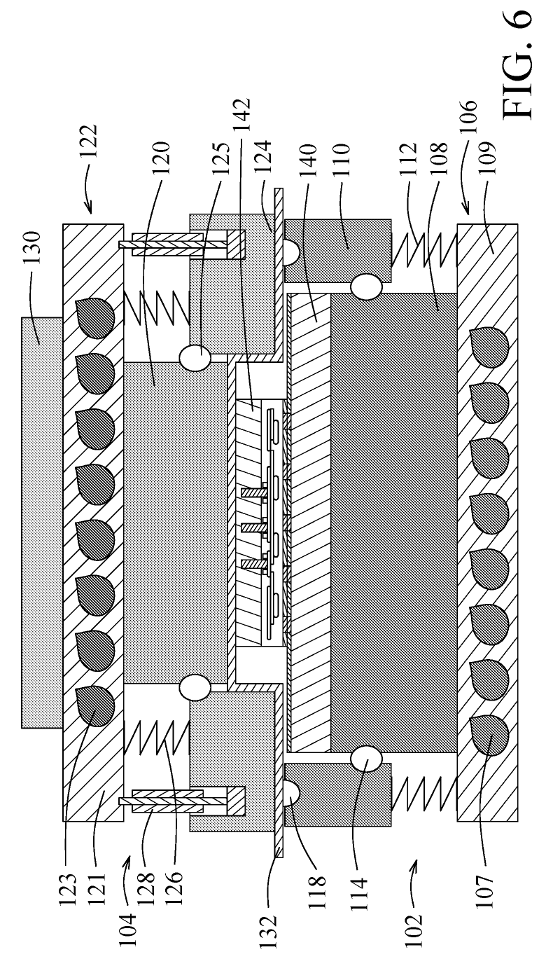

As shown in FIG. 6, the upper portion 104 is lowered so the portion of the release layer 132 in contact with the top member 120 is in contact with the die 142. The portion of the release layer 132 in contact with the top clamp 124 is in contact with the sealing member 118 and is not in contact with the wafer 140, as shown in FIG. 6. During operation, the wafer 140 and the die 142 are heated to an elevated temperature, and the top member 120 presses lightly on the die 142. In some embodiments, the bottom heater 106 heats the support 108 to an elevated temperature, such as from about 150 degrees Celsius to about 210 degrees Celsius, for example about 180 degrees Celsius, prior to lowering the upper portion 104 to be in contact with the release layer 132. The top heater 122 heats the top member 120 to an elevated temperature, such as from about 40 degrees Celsius to about 60 degrees Celsius, for example about 50 degrees Celsius, prior to lowering the upper portion 104 to be in contact with the release layer 132. It has been discovered that at these temperatures, as the top member 120 presses on the die 142, the covalent bonds between atoms from the wafer 140 and the die 142 are formed at a rate to allow the air bubbles between the wafer 140 and the die 142 to be pressed out. If the temperatures of the top member 120 is too high, the covalent bonds may be formed too fast, and the air bubbles may be trapped between the wafer 140 and the die 142. Furthermore, at these temperatures, the warpage of the die 142 may be removed as a result of the edges of the die 142 being pre-bonded to the wafer 140. In other words, there may be corner non-bonding between the die 142 and the wafer 140.

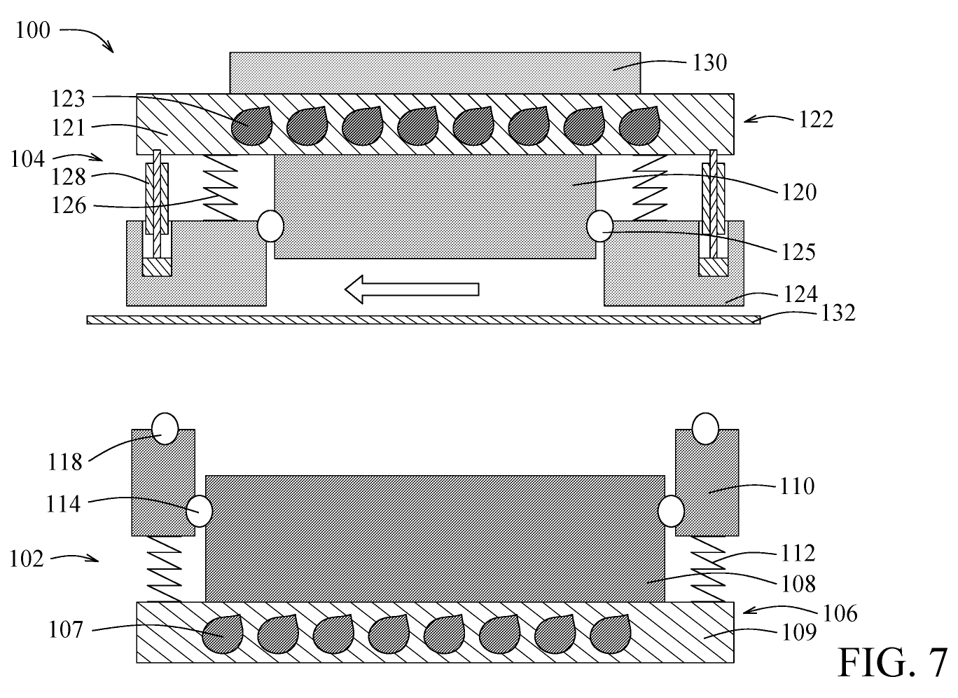

In some embodiments, after pressing on the die 142 for a predetermined time duration, the heat from the support 108 transfers to the top member 120 to increase the temperature of the top member 120. In some embodiments, the time duration ranges from about 5 minutes to about 10 minutes, such as about 6 minutes, and the temperature of the top member 120 is increased by about 10 to about 12 percent. In some embodiments, the temperature of the top member 120 is increased from about 50 degrees Celsius to about 57 degrees Celsius. Next, as shown in FIG. 7, the upper portion 104 is lifted up, and the wafer 140 with the die 142 pre-bonded thereon is removed from the support 108. In some embodiments, air may be flowed below the top member 120 (indicated by the arrow) to cool the top member 120. The cooling rate of using the air flow may be about 0.11 degrees Celsius per minute. Thus, in some embodiments, it may take over 60 minutes to cool the top member 120 from 57 degrees Celsius to 50 degrees Celsius. However, there may be less than 10 minutes before the next wafer and die to be pre-bonded by the bonding apparatus 100. Thus, in some embodiments, the temperature of the top member 120 may be greater than 50 degrees Celsius during the pre-bonding process. As a result, air bubbles may be trapped at the interface between the die and the wafer. In some embodiments, the air bubbles may be located near the edge of the die, and the subsequent annealing process may cause the size of the air bubbles to increase. As a result, the edges of the die may be separated from the die, and the bottom surface of the die may be convex again. In other words, the die may be warped as when it was placed on the wafer.

In some embodiments, in order to increase the cooling of the top member 120, the cooling plate 130 is utilized. In some embodiments, the cooling plate 130 is a distinct plate disposed on the top heater 122, as shown in FIG. 7. The cooling plate 130 is described in detail below. In some embodiments, a coolant, such as water or glycol, may be flowed through the cooling plate to cool the top member 120 after the upper portion 104 is lifted up from the die 142. If the cooling plate 130 starts to cool the top member 120 before the upper portion 104 is lifted up, the rate of the formation of covalent bonds between atoms from the wafer 140 and the die 142 may be too slow. Thus, in some embodiments, the coolant does not enter the cooling plate 130 before the upper portion 104 is lifted from the die 142. After the top member 120 reaches the predetermined temperature, such as about 50 degrees Celsius, the coolant stops flowing through the cooling plate 130, and the next wafer and die are placed in the bonding apparatus 100. With the cooling plate 130 cooling the top member 120, the cooling rate of the top member 120 is increased to 3.7 degrees Celsius per minute, and it takes less than three minutes to cool the top member 120 from 57 degrees Celsius to 50 degrees Celsius. As the next wafer and die are placed in the bonding apparatus 100 to be pre-bonded, the temperature of the top member 120 is cooled to 50 degrees Celsius.

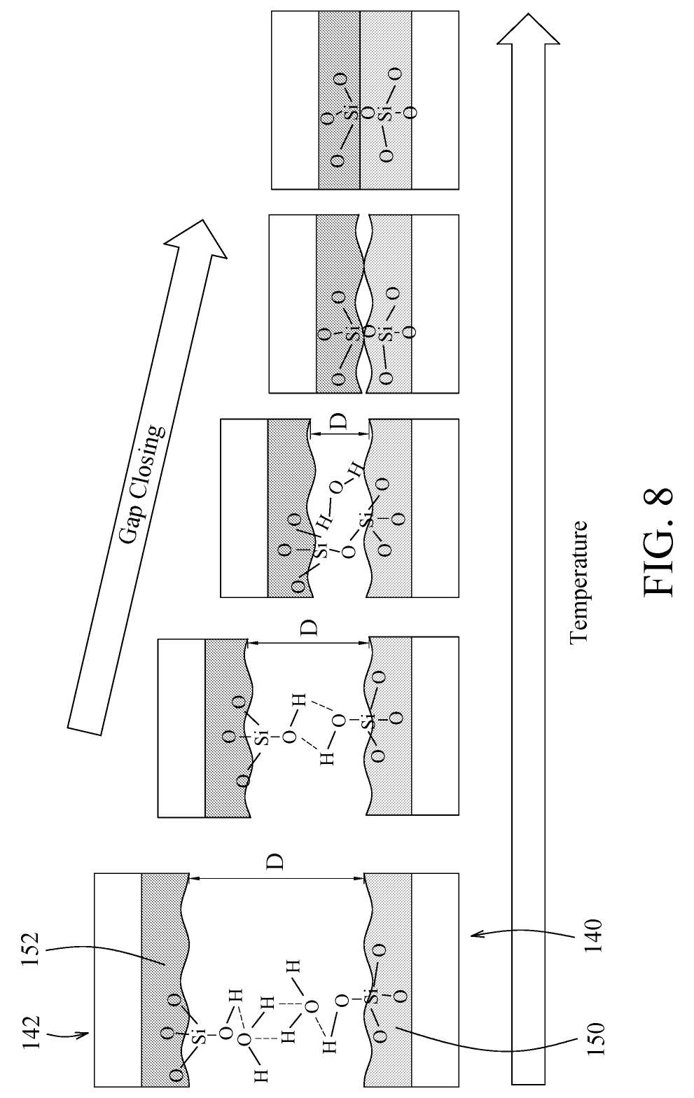

FIG. 8 illustrates the die 142 and the wafer 140 being pre-bonded in the bonding apparatus 100, in accordance with some embodiments. As shown in FIG. 8, when the die 142 is placed on the wafer 140, a gap with a distance D is between a top layer 150 of the wafer 140 and a bottom layer 152 of the die 142. The top layer 150 may be the surface dielectric layer 34 shown in FIG. 3, and the bottom layer 152 may be the dielectric layer 52A or 52B shown in FIG. 3. In some embodiments, the top layer 150 of the wafer 140 is a SiON layer, and the bottom layer 152 of the die 142 is a SiO₂ layer. In some embodiments, the distance D is about 11.5 angstroms, and hydrogen bonds between the atoms of the top layer 150 and the bottom layer 152 are formed in the gap. As the top member 120 (FIG. 6) presses on the die 142, the distance D of the gap is getting smaller, as shown in FIG. 8. The distance D may be decreased to 6 angstroms then to 3.2 angstroms. Then, the gap becomes discrete air bubbles, as shown in FIG. 8. Lastly, the air bubbles are squeezed out, and the Si-O-Si covalent bonds are formed between the atoms of the wafer 140 and the die 142. While the top member 120 is pressing on the die 142, the temperature of the wafer 140 and the die 142 is also increasing due to the bottom heater 106 (FIG. 6). Thus, with pressure applied to the die 142 at elevated temperature, the amount of time for the pre-bonding process may be short, such as from about 5 minutes to about 10 minutes, for example about 6 min. The time of the pre-bonding process is substantially shorter than the time of the anneal process described in FIG. 2.

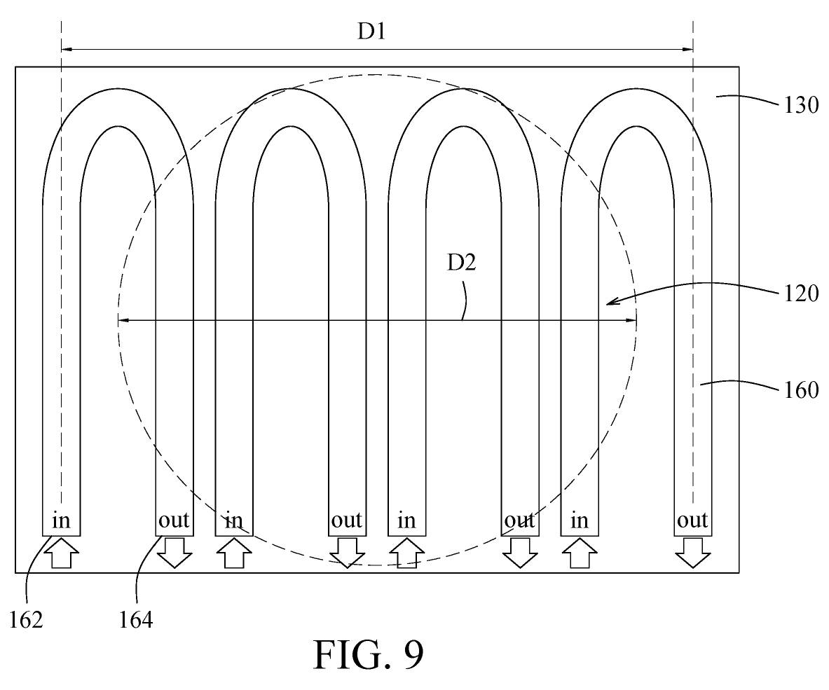

FIGS. 9, 10, 11, 12, 13, and 14 are top view of the cooling plate 130 of the bonding apparatus 100, in accordance with some embodiments. As shown in FIG. 9, in some embodiments, the cooling plate 130 includes a plurality of channels 160 formed therein. Each channel 160 may have a U shape and may have an inlet 162 and an outlet 164 on the same side of the cooling plate 130. The top member 120, which is shown using dotted lines, is located below the cooling plate 130. In some embodiments, the plurality of channels 160 extends along a length of the cooling plate 130, and the length of the cooling plate 130 is greater than a diameter D2 of the top member 120, as shown in FIG. 9. In some embodiments, four U shaped channels 160 are formed in the cooling plate 130, and the four channels 160 extends over the diameter D2 of the top member 120. In some embodiments, a distance D1 between the outermost channels 160 is greater than the diameter D2 of the top member 120. During operation, a coolant is flowed through the channels 160 via the inlets 162 and outlets 164. In some embodiments, the inlet 162 and the outlet 164 are similarly arranged for all channels 160. For example, in some embodiments, for each channel 160, the inlet 162 is on the left side, and the outlet 164 is on the right side.

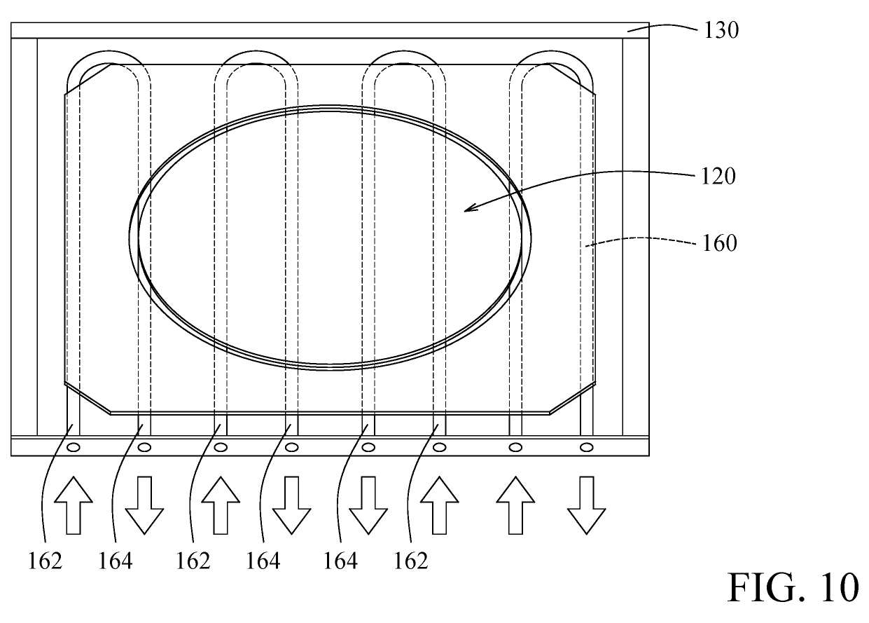

In some embodiments, as shown in FIG. 10, the cooling plate 130 includes four channels 160 located therein, and the middle two channels 160 are mirror images of each other. For example, the left channel 160 of the middle two channels 160 has an inlet 162 on the left side and an outlet 164 on the right side, and the right channel 160 of the middle two channels 160 has an inlet 162 on the right side and an outlet 164 on the left side. Thus, in some embodiments, the outlets 164 of the middle two channels 160 are immediately adjacent to each other. In some embodiments, with the cooling plate 130 having the channels 160 as shown in FIG. 10, the cooling of the top member 120 from 57 degrees Celsius to 50 degrees Celsius took about 276.0 seconds to about 310.4 seconds, and the resulting temperature profile of the bottom surface of the top member 120 is substantially uniform, such as having a relative standard deviation of about 3.7 percent to about 4.2 percent. In some embodiments, the flow rate of the coolant flowing through the channels 160 may range from about 20 liters per minute (LPM) to about 40 LPM. In the embodiments that the flow rate of the coolant is about 20 LPM, the time duration for cooling the top member 120 from 57 degrees Celsius to 50 degrees Celsius was about 310.4 seconds, and the relative standard deviation of the temperature profile of the bottom surface of the top member 120 is about 3.7 percent. In the embodiment that the flow rate of the coolant is about 40 LPM, the time duration for cooling the top member 120 from 57 degrees Celsius to 50 degrees Celsius was about 276.0 seconds, and the relative standard deviation of the temperature profile of the bottom surface of the top member 120 is about 4.2 percent. Thus, with the faster flow rate, the cooling of the top member 120 is faster, but the temperature uniformity of the bottom surface of the top member 120 is worse.

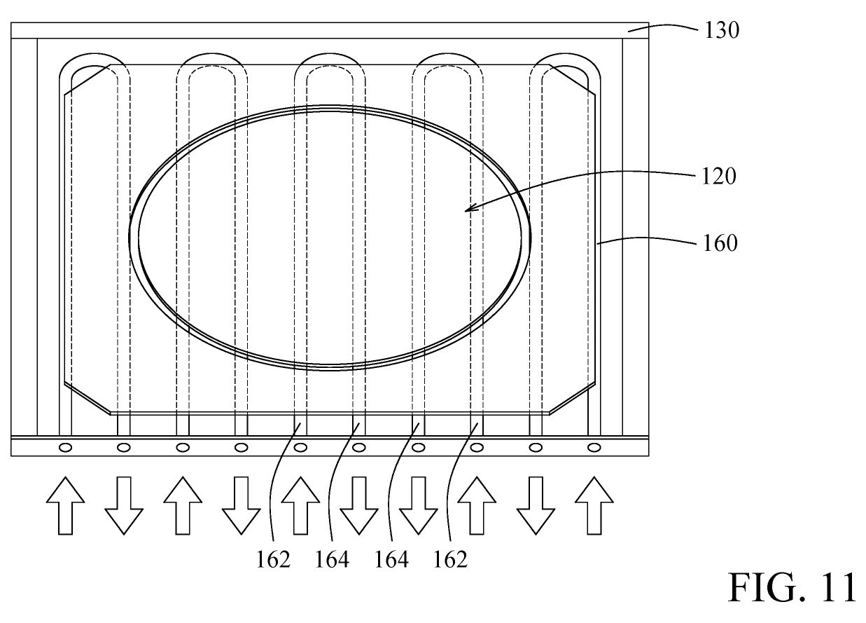

In some embodiments, as shown in FIG. 11, more than four channels 160 are located in the cooling plate 130. For example, five channels 160 are located in the cooling plate 130. In some embodiments, the inlets 162 and the outlets 164 of the channels 160 are arranged in the same way, such that the inlets 162 of the channels 160 are located on the left side, and the outlets 164 of the channels are located on the right side. In some embodiments, the inlets 162 and the outlets 164 of one or more channels 160 have different arrangements. For example, as shown in FIG. 11, the third channel 160 and the fourth channel 160 from the left side are mirror images of each other. The third channel 160 has an inlet 162 on the left side and an outlet 164 on the right side, and the fourth channel 160 has an inlet 162 on the right side and an outlet 164 on the left side. Thus, in some embodiments, the outlets 164 of the third and fourth channels 160 are immediately adjacent to each other. In some embodiments, the outside channels 160 are not directly over the top member 120, as shown in FIG. 11. In some embodiments, one of the two outside channels 160 is not directly over the top member 120. In some embodiments, all five channels 160 are directly over the top member 120. The different arrangements of the channels 160 may cool the top member 120 more efficiently based on the temperature profile of the top member 120.

In some embodiments, with the cooling plate 130 having the channels 160 as shown in FIG. 11, the cooling of the top member 120 from 57 degrees Celsius to 50 degrees Celsius took about 264.2 seconds to about 299.4 seconds, and the resulting temperature profile of the bottom surface of the top member 120 has a relative standard deviation of about 4.0 percent to about 4.6 percent. In some embodiments, the flow rate of the coolant flowing through the channels 160 may range from about 20 LPM to about 40 LPM. In the embodiments that the flow rate of the coolant is about 20 LPM, the time duration for cooling the top member 120 from 57 degrees Celsius to 50 degrees Celsius was about 299.4 seconds, and the relative standard deviation of the temperature profile of the bottom surface of the top member 120 is about 4.0 percent. In the embodiment that the flow rate of the coolant is about 40 LPM, the time duration for cooling the top member 120 from 57 degrees Celsius to 50 degrees Celsius was about 264.2 seconds, and the relative standard deviation of the temperature profile of the bottom surface of the top member 120 is about 4.6 percent. Compared to the cooling plate 130 shown in FIG. 10, the cooling plate 130 shown in FIG. 11 can achieve faster cooling of the top member 120 but with worse temperature uniformity of the bottom surface of the top member 120.

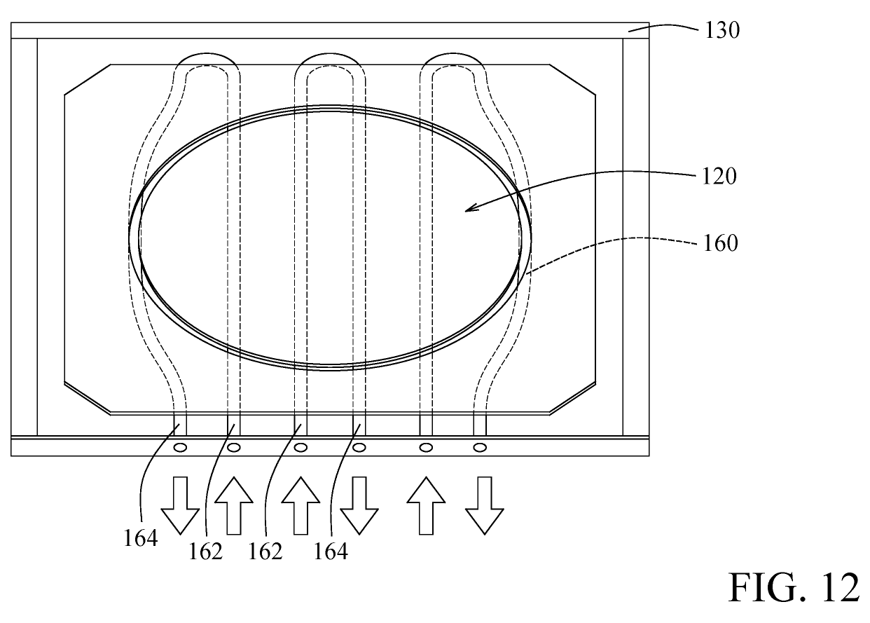

In some embodiments, as shown in FIG. 12, less than four channels 160 are located in the cooling plate 130. For example, three channels 160 are located in the cooling plate 130. In some embodiments, the three channels 160 may be identical. In some embodiments, the outside channels 160 of the three channels 160 have a shape different from the middle channel 160 of the three channels 160, as shown in FIG. 12. For example, in some embodiments, each outside channel 160 includes a straight portion connected to a curved portion. The shape of a portion of the curved portion may conform to the shape of a portion of the edge of the top member 120 disposed below. In other words, the portion of the curved portion may be directly above the portion of the edge of the top member 120, as shown in FIG. 12. The curved portion of the outside channels 160 may cool the top member 120 more efficiently.

In some embodiments, the inlets 162 and the outlets 164 of the channels 160 are arranged in the same way, such that the inlets 162 of the channels 160 are located on the left side, and the outlets 164 of the channels are located on the right side. In some embodiments, the inlets 162 and the outlets 164 of one or more channels 160 have different arrangements. For example, as shown in FIG. 12, the inlets 162 of the first channel 160 and the second channel 160 from the left side are immediately adjacent to each other, while the outlet 164 of the second channel is immediately adjacent to the inlet 162 of the third channel 160, as shown in FIG. 12.

In some embodiments, with the cooling plate 130 having the channels 160 as shown in FIG. 12, the cooling of the top member 120 from 57 degrees Celsius to 50 degrees Celsius took about 293.1 seconds to about 321.9 seconds, and the resulting temperature profile of the bottom surface of the top member 120 has a relative standard deviation of about 4.9 percent to about 5.4 percent. In some embodiments, the flow rate of the coolant flowing through the channels 160 may range from about 20 LPM to about 40 LPM. In the embodiments that the flow rate of the coolant is about 20 LPM, the time duration for cooling the top member 120 from 57 degrees Celsius to 50 degrees Celsius was about 321.9 seconds, and the relative standard deviation of the temperature profile of the bottom surface of the top member 120 is about 4.9 percent. In the embodiment that the flow rate of the coolant is about 40 LPM, the time duration for cooling the top member 120 from 57 degrees Celsius to 50 degrees Celsius was about 293.1 seconds, and the relative standard deviation of the temperature profile of the bottom surface of the top member 120 is about 5.4 percent. Compared to the cooling plate 130 shown in FIGS. 10 and 11, the cooling plate 130 shown in FIG. 12 leads to slower cooling of the top member 120 and with worse temperature uniformity of the bottom surface of the top member 120.

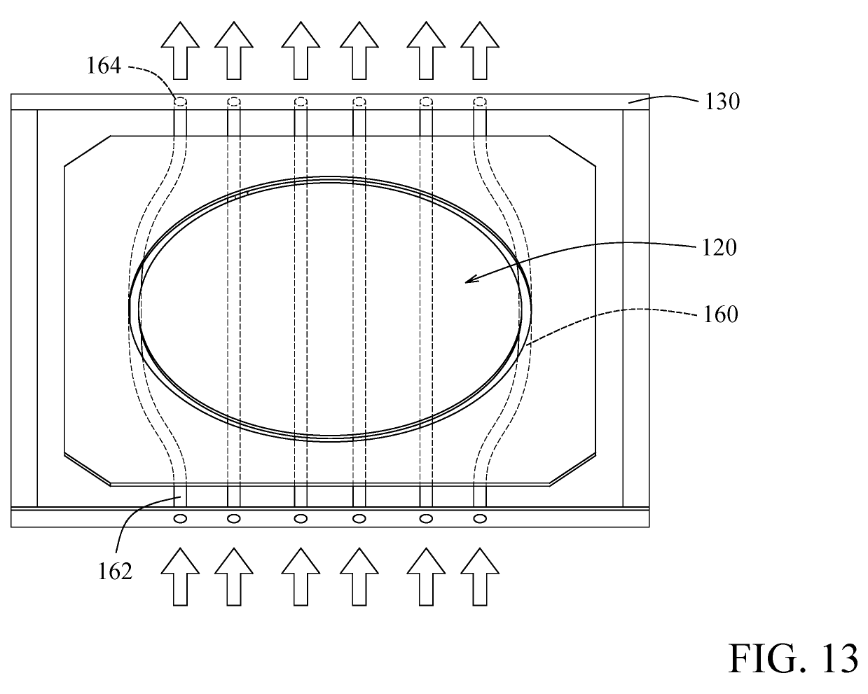

In some embodiments, as shown in FIG. 13, instead of having a U shape, the channels 160 extend from one side of the cooling plate 130 to the opposite side of the cooling plate 130. For example, the inlets 162 of the channels 160 are located at a first side of the cooling plate 130, and the outlets 164 of the channels 160 are located at a second side opposite the first side of the cooling plate 130. The number of channels 160 may range from about 3 to about 10, such as from about 4 to about 6. The channels 160 may extend spaced apart across the diameter of the top member 120. In some embodiments, each channel 160 is substantially straight. In some embodiments, the center channels 160 are substantially straight, and the outside channels 160 may be curved. For example, each of the outside channels 160 may include a portion that conforms to the shape of a portion of the top member 120, as shown in FIG. 13.

In some embodiments, with the cooling plate 130 having the channels 160 as shown in FIG. 13, the cooling of the top member 120 from 57 degrees Celsius to 50 degrees Celsius took about 344.4 seconds, and the resulting temperature profile of the bottom surface of the top member 120 has a relative standard deviation of about 4.6 percent.

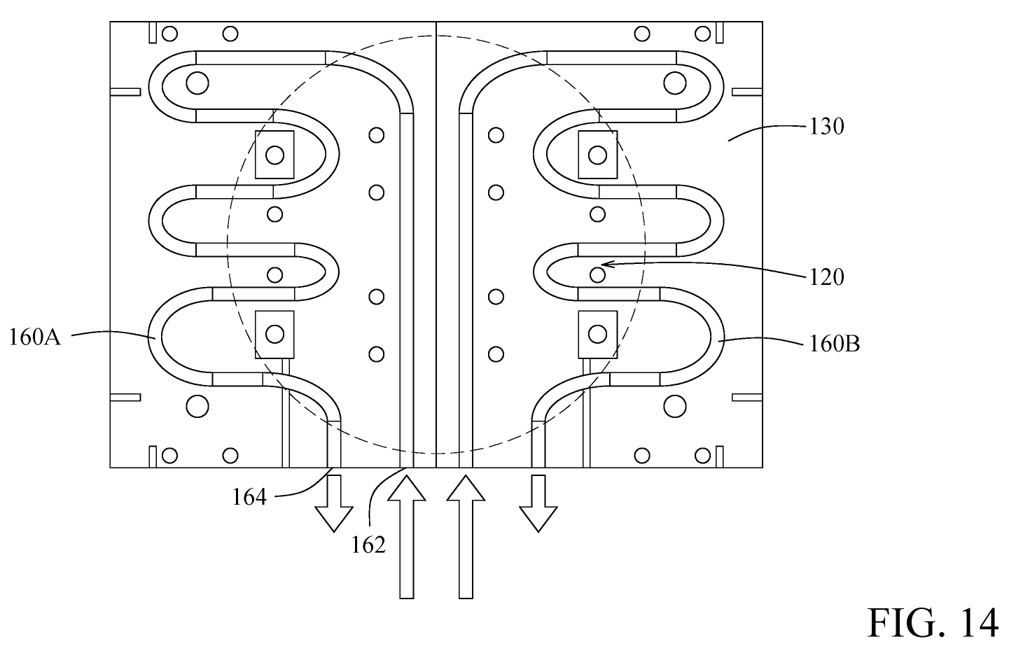

In some embodiments, as shown in FIG. 14, the cooling plate 130 includes two channels 160A, 160B located therein. The channels 160A, 160B may be mirror images of each other, as shown in FIG. 14. In some embodiments, each channel 160A, 160B includes a straight portion connected to a serpentine portion. In some embodiments, the channels 160A, 160B are symmetric with respect to the diameter of the top member 120, as shown in FIG. 14. In some embodiments, with the cooling plate 130 having the channels 160 as shown in FIG. 14, the cooling of the top member 120 from 57 degrees Celsius to 50 degrees Celsius took about 350.0 seconds, and the resulting temperature profile of the bottom surface of the top member 120 has a relative standard deviation of about 4.9 percent.

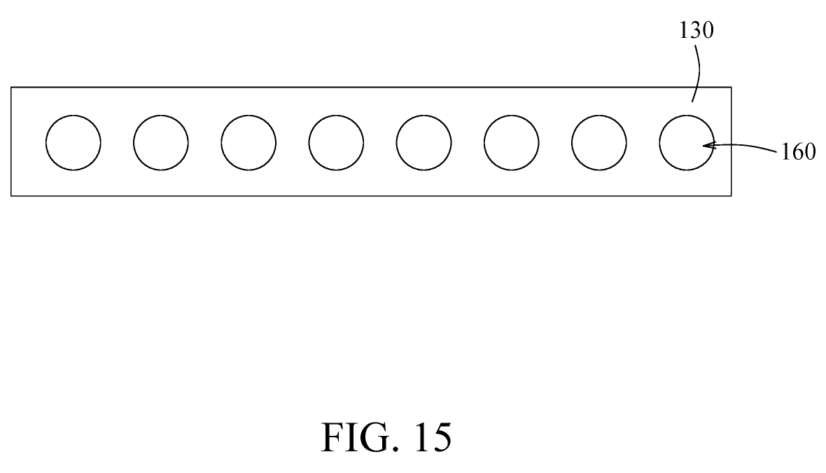

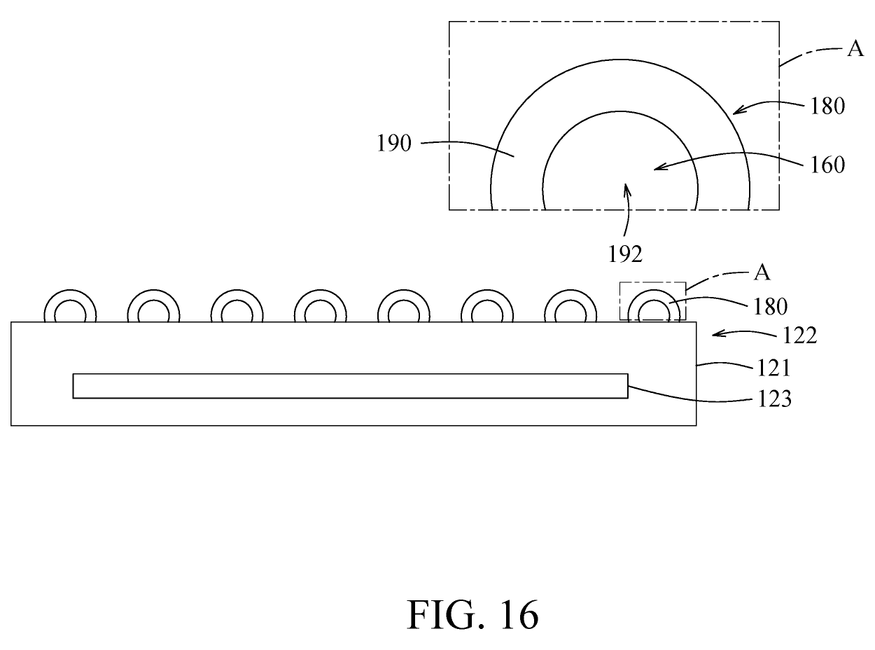

FIGS. 15, 16, and 17 are cross-sectional side views of a portion of the bonding apparatus 100, in accordance with some embodiments. As shown in FIG. 15, the bonding apparatus 100 includes the cooling plate 130, and the channels 160 are formed in the cooling plate 130. The channels 160 may be formed in the cooling plate 130 by any suitable method, such as drilling or boring. In some embodiments, as shown in FIG. 16, pipes 180 are placed on the top member 120 without the cooling plate 130, and the channels 160 are formed in the pipes 180. The pipes 180 may have the same shapes as the channels 160 shown in FIGS. 9-14. In some embodiments, each pipe 180 has circular cross-sections and is secured to the top of the top member 120 by any suitable means, such as fasteners. In some embodiments, in order to achieve more efficient heat transfer, the channel 160 within the pipe 180 is exposed to the top surface of the plate 121 of the top heater 122, as shown in FIG. 16. For example, the pipe 180 includes a structure 190 having an opening 192. The bottom of the structure 190 may be substantially flat, so the structure 190 can be secured on the flat top surface of the plate 121. The structure 190 is secured to the top surface of the plate 121 by a method that prevents the coolant from leaking out. In some embodiments, the structure 190 is glued to the plate 121. During operation, the coolant flows through the structure 190 and the coolant is in direct contact with the plate 121. In some embodiments, the pipe 180 has an inner diameter of about 25 mm and an outer diameter of about 33 mm.

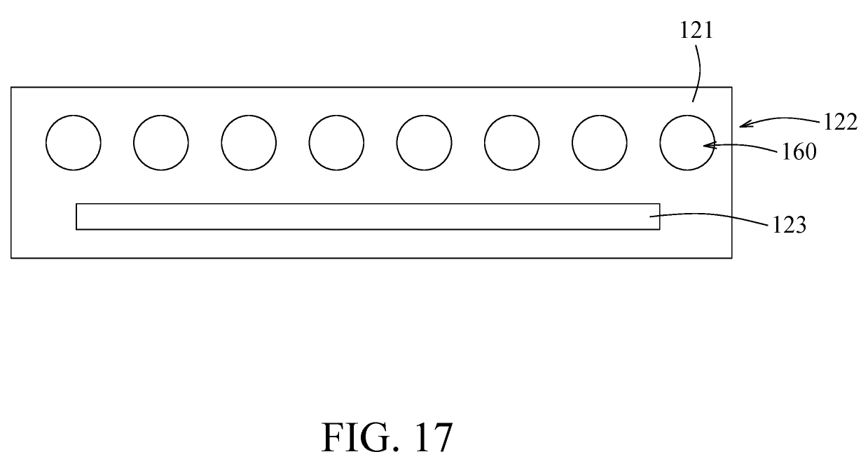

In some embodiments, as shown in FIG. 17, the channels 160 are formed in the plate 121 of the top heater 122. For example, the channels 160 may be formed over or below the heating element 123. In some embodiments, the channels 160 are formed over the heating element 123, as shown in FIG. 17. As a result, the controlling of the heating element 123 may be improved.

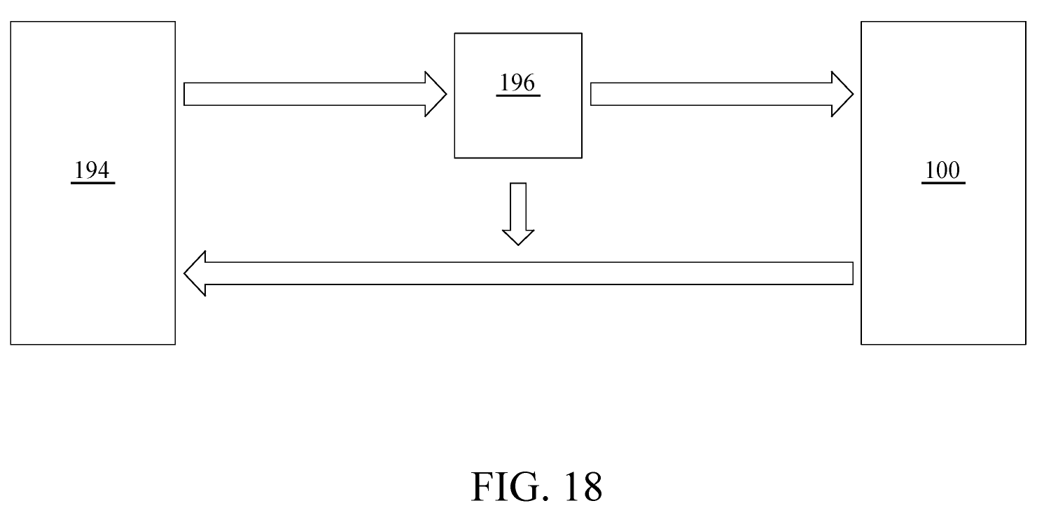

FIG. 18 schematic illustrates a three-way valve 196 for controlling the flow of a coolant, in accordance with some embodiments. In some embodiments, the three-way valve 196 is placed between a coolant source 194 and the bonding apparatus 100. When the temperature of the top member 120 is at 50 degrees, the three-way valve 196 operates to circulate the coolant between the coolant source 194 and the three-way valve 196, as shown in FIG. 18. When the temperature of the top member 120 is greater than 50 degrees and when the top member 120 is lifted from the die after the pre-bonding process, the three-way valve 196 operates to circulate the coolant between the coolant source 194 and the bonding apparatus 100. In other words, even if the coolant is not needed in the bonding apparatus 100, the coolant is still circulating at the predetermined temperature. As a result, the time for the coolant at the predetermined temperature to reach the bonding apparatus 100 may be reduced.

Embodiments of the present disclosure provide a bonding apparatus 100 and methods of operating thereof. In some embodiments, the bonding apparatus 100 includes channels 160 or pipes 180 for a coolant to flow therethrough to cool a top member 120. The channels 160 may be located in a cooling plate 130 disposed on the top heater 122, in a plate 121 of the top heater 122, or in the top member 120. The pipes 180 may be disposed on the plate 121 of the top heater 122. Some embodiments may achieve advantages. For example, with the coolant to cool the top member 120, the temperature of the top member 120 is cooled to the predetermined temperature prior to performing the pre-bonding process. As a result, various defects, such as corner non-bonding or air bubbles at the interface, may be reduced.

An embodiment is a method. The method includes heating a support to a first temperature, and a first wafer and a first die are disposed on the support. The method further includes heating a top member to a second temperature less than the first temperature and lowering the top member to press on the first die. The second temperature of the top member is increased. The method further includes lifting the top member from the first die, cooling the top member to the second temperature using a coolant, and lowering the top member to press on a second die.

Another embodiment is a method. The method includes placing a first wafer on a support in a bonding apparatus, and a first die is disposed on the first wafer. The method further includes performing a first pre-bonding process on the first die and the first wafer by heating the first wafer and the first die and pressing on the first die by a top member, and a temperature of the top member is increased during the first pre-bonding process. The method further includes lifting the top member from the first die, cooling the top member by flowing a coolant through channels located over the top member, and placing a second wafer on the support in the bonding apparatus. A second die is disposed on the second wafer. The method further includes performing a second pre-bonding process on the second die and the second wafer.

A further embodiment is a bonding apparatus. The bonding apparatus includes a bottom heater, a support disposed over the bottom heater, a top member disposed over the support, a top heater disposed over the top member, and a plurality of channels disposed over the top heater.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
heating a support to a first temperature, wherein a first wafer and a first die are disposed on the support;
heating a top member to a second temperature less than the first temperature;
lowering the top member to press on the first die, wherein the second temperature of the top member is increased;
lifting the top member from the first die;
cooling the top member to the second temperature using a coolant; and
lowering the top member to press on a second die.

2. The method of claim 1, wherein the support is heated by a bottom heater located below the support.

3. The method of claim 2, wherein the top member is heated by a top heater located above the top member.

4. The method of claim 3, wherein the first temperature ranges from about 150 degrees Celsius to about 210 degrees Celsius.

5. The method of claim 4, wherein the second temperature ranges from about 40 degrees Celsius to about 60 degrees Celsius.

6. The method of claim 1, wherein the coolant is flowed through channels located over the top member.

7. The method of claim 6, wherein the channels are formed in a cooling plate located over the top member.

8. The method of claim 6, wherein the channels are inside of pipes located over the top member.

9. The method of claim 1, wherein the coolant is flowed through channels located in the top member.

10. A method, comprising:
placing a first wafer on a support in a bonding apparatus, wherein a first die is disposed on the first wafer;
performing a first pre-bonding process on the first die and the first wafer by heating the first wafer and the first die and pressing on the first die by a top member, wherein a temperature of the top member is increased during the first pre-bonding process;
lifting the top member from the first die;
cooling the top member by flowing a coolant through channels located over the top member;
placing a second wafer on the support in the bonding apparatus, wherein a second die is disposed on the second wafer; and
performing a second pre-bonding process on the second die and the second wafer.

11. The method of claim 10, wherein the coolant is water.

12. The method of claim 10, wherein a flow rate of the coolant ranges from about 20 liters per minute to about 40 liters per minute.

13. The method of claim 10, wherein the top member is cooled to a predetermined temperature in less than three minutes.

14. The method of claim 10, wherein the coolant is circulating between a coolant source and a three-way valve prior to entering the bonding apparatus.

15. The method of claim 10, wherein the temperature of the top member is increased by about 10 to 12 percent.

16. A bonding apparatus, comprising:
a bottom heater;
a support disposed over the bottom heater;
a top member disposed over the support;
a top heater disposed over the top member; and
a plurality of channels disposed over the top heater.

17. The bonding apparatus of claim 16, wherein the plurality of channels are formed in a cooling plate disposed on the top heater.

18. The bonding apparatus of claim 16, wherein the plurality of channels are formed in a plurality of pipes disposed on the top heater.

19. The bonding apparatus of claim 18, wherein each channel of the plurality of channels is exposed to a top surface of the top heater.

20. The bonding apparatus of claim 16, wherein the plurality of channels comprises three, four, or five channels.
